(19) United States
(12) Patent Application Publication
(10) Pub. No.: US 2021/0204401 A1
(43) Pub. Date: Jul. 1, 2021

(54) FLEXIBLE CIRCUIT BOARD HAVING A STIFFENING STRUCTURE

(71) Applicant: CHIPBOND TECHNOLOGY CORPORATION, Hsinchu (TW)

(72) Inventors: Yu-Chen Ma, Kaohsiung City (TW); Hsin-Hao Huang, Kaohsiung City (TW); Wen-Fu Chou, Kaohsiung City (TW); Gwo-Shyan Sheu, Kaohsiung City (TW)

(21) Appl. No.: 16/914,861

(22) Filed: Jun. 29, 2020

(30) Foreign Application Priority Data
Dec. 31, 2019 (TW) 108148745

(51) Int. Cl. H05K 1/02

(52) U.S. Cl. CPC H05K 1/0281; H05K 3/0052; H05K 1/0269

(57) ABSTRACT

A flexible circuit board includes a flexible substrate and a stiffening structure, a stiffening area is defined on a bottom surface of the flexible substrate, and the stiffening structure includes a first stiffener and a second stiffener. The first stiffener is disposed on the stiffening area of the bottom surface and the second stiffener is disposed on the first stiffener such that the first stiffener is located between the flexible substrate and the second stiffener. The flexible substrate is protected from punch damage caused by stress concentrations because a cutting line of the flexible substrate only passes through the first stiffener.

### FIELD OF THE INVENTION

This invention relates to a flexible circuit board, and more particularly to a flexible circuit board having stiffening structure.

### BACKGROUND OF THE INVENTION

Display panel is going to be thinner and lighter so flexible circuit boards used to control driver integrated circuit (driver IC) of panel have to be reduced to less than 50 um in thickness. However, the less the thickness of flexible circuit boards are, the less the strength of flexible circuit board have. Outer leads of flexible circuit board may be difficult to connect to drive circuit connector. In prior art, a stiffener may be disposed under the outer leads of the flexible circuit board to increase strength partially, but the presence of large height difference between the surfaces of the stiffener and the flexible circuit board may cause stress concentrations in the connection between the stiffener and the flexible circuit board during punching process to damage the flexible circuit board.

### SUMMARY

The present invention provides a stiffening structure composed of first and second stiffeners to enhance strength of a flexible substrate. The stiffening structure not only provide sufficient support but also prevent stress concentrations such that the flexible substrate is protected from damage during punching.

A flexible circuit board of the present invention includes a flexible substrate and a stiffening structure. The flexible substrate includes a film and a patterned circuit layer located on a top surface of the film, and a stiffening area is defined on a bottom surface of the film. The stiffening structure includes a first stiffener and a second stiffener, the first stiffener is disposed on the stiffening area of the bottom surface and the second stiffener is disposed on the first stiffener such that the first stiffener is located between the film and the second stiffener. A cutting line defined on the flexible substrate only passes through the first stiffener of the stiffening structure.

The stiffening structure provides sufficient stiffness to support the flexible substrate and the cutting line defined on the flexible substrate only passes through the first stiffener to reduce stress concentrations so as to protect the flexible substrate from punch damage.

### DESCRIPTION OF THE DRAWINGS

FIG. 1 is a top view diagram illustrating a flexible circuit board in accordance with one embodiment of the present invention.

FIG. 2 is a bottom view diagram illustrating a flexible circuit board in accordance with one embodiment of the present invention.

FIG. 3 is a cross-section view diagram illustrating a flexible circuit board in accordance with one embodiment of the present invention.

FIGS. 4(a) to 4(e) are diagrams illustrating a stiffening structure and alignment marks in accordance with different embodiments of the present invention.

### DETAILED DESCRIPTION OF THE INVENTION

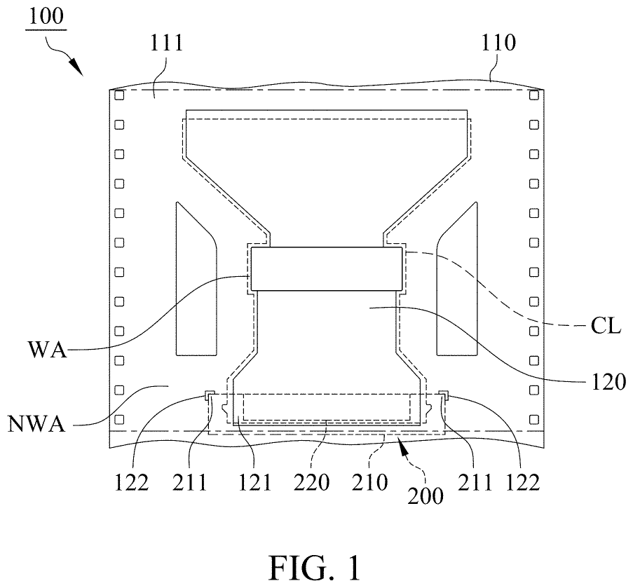

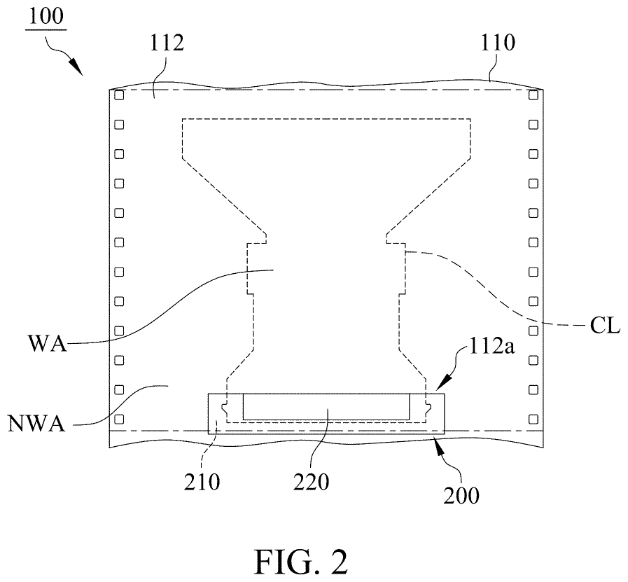

FIGS. 1 and 2 are top and bottom view diagrams illustrating a flexible circuit board of the present invention, respectively, the flexible circuit board includes a flexible substrate 100 and a stiffening structure 200. The flexible substrate 100 includes a film 110 and a patterned circuit layer 120 located on a top surface 111 of the film 110, the film 110 may be polyimide (PI) or polyethylene terephthalate (PET) film and the patterned circuit layer 120 may be made by etching a copper layer electroplated or cladded on the film 110.

With reference to FIG. 1, the flexible substrate 100 is a tape in roll form and has sprocket holes at two-sided edges for roll-to-roll processes, such as copper plating, photoresist coating, photolithography, solder resist coating and chip mounting. A cutting line CL is defined on the flexible substrate 100 for clarifying punching range, and the flexible substrate 100 is punched along the defined cutting line CL to become a final product. A working area WA surrounded by the cutting line CL and a non-working area NWA outside the cutting line CL are defined on the flexible substrate 100. The working area WA is separated as a driver IC and the non-working area NWA is left as a waste after the punching process.

The patterned circuit layer 120 of FIG. 1 is simplified, in fact, the patterned circuit layer 120 is composed of a great number of fine traces. The patterned circuit layer 120 includes an outer lead section 121 which is located at the edge of the flexible substrate 100 and within the working area WA. The outer lead section 121 is configured to connect with a connector of drive circuit for signal transmission. With reference to FIGS. 1 and 2, a stiffening area 112a is defined on a bottom surface 112 of the film 110. In this embodiment, the strength of the outer lead section 121 used to connect with the drive circuit requires to be enhanced such that the stiffening area 112a defined on the bottom surface 112 is located under the outer lead section 121. However, in other embodiment, the stiffening area 112a can be also located under other area that requires support stiffness.

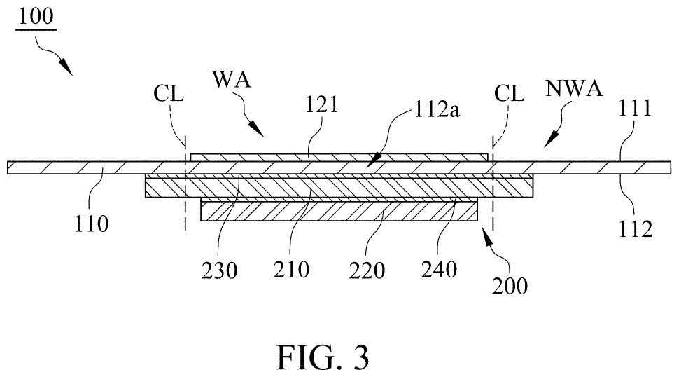

With reference to FIGS. 2 and 3, the stiffening structure 200 is disposed on the stiffening area 112a of the bottom surface 112, and in this embodiment, the stiffening structure 200 includes a first stiffener 210 and a second stiffener 220. The first stiffener 210 is disposed on the stiffening area 112a of the bottom surface 112 and the second stiffener 220 is disposed on the first stiffener 210 such that the first stiffener 210 is located between the film 110 and the second stiffener 220. As shown in FIG. 3, the stiffening structure 200 preferably further includes a first adhesive layer 230 and a second adhesive layer 240. The first adhesive layer 230 is located between the film 110 and the first stiffener 210 and provided for connecting the film 110 and the first stiffener 210, the second adhesive layer 240 is located between the first stiffener 210 and the second stiffener 220 for connecting the first stiffener 210 and the second stiffener 220.

With reference to FIGS. 2 and 3, the first stiffener 210 and the second stiffener 220 may be made of polyimide (PI) or polyethylene terephthalate (PET), and a thickness of the first stiffener 210 is more than or equal to a thickness of the second stiffener 220. The double-layer stack of the first stiffener 210 and the second stiffener 220 can provide sufficient support stiffness for the flexible substrate 100. Preferably, the second stiffener 220 is smaller than the first stiffener 210 and totally located within the working area WA, and the first stiffener 210 is located on both of the working area WA and the non-working area NWA. The cutting line CL only passes through the first stiffener 210, not pass through the second stiffener 220, accordingly, punch tool cut the first stiffener 210 but not cut the second stiffener 220 when punching the flexible substrate 100. The height difference between single-layer stiffener and the bottom surface 112 is less than that between two-layer stiffener and the bottom surface 112. Consequently, the first stiffener 210 is cut along the cutting line CL with less stress concentrations during the punching process to prevent connection broken between the film 110 and the stiffening structure 200.

With reference to FIG. 1, the patterned circuit layer 120 includes two alignment marks 122 which are L-shaped. The top view of the flexible circuit board shows that two corners 211 of the first stiffener 210 are aligned to corners of the L-shaped alignment marks 122 while sticking the first stiffener 210 on the bottom surface 112. The second stiffener 220 is positioned and adhered on the first stiffener 210 by aligning the second stiffener 220 with the edge of the first stiffener 210 and the outer lead section 121 of the patterned circuit layer 120.

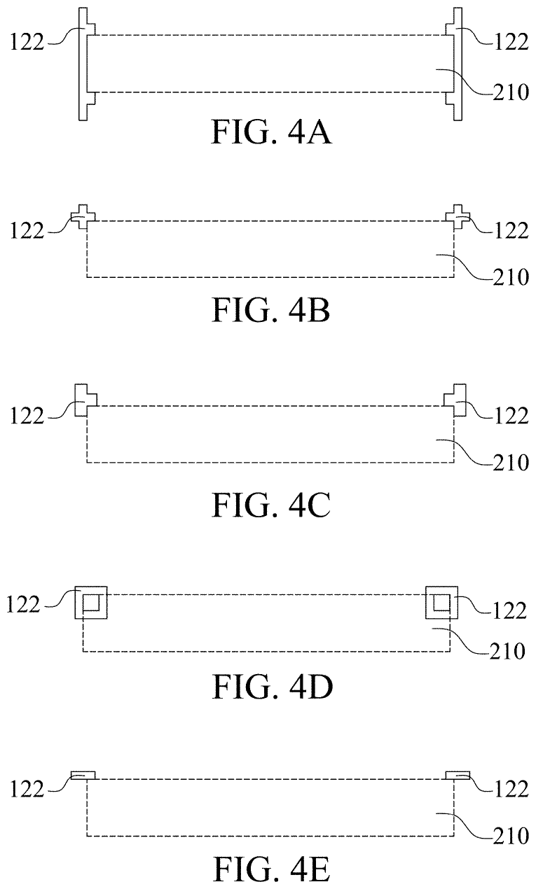

With reference to FIG. 4, in other embodiments, the alignment marks 122 may be (a) double convex (as shown in FIG. 4(a)), (b) christcross (as shown in FIG. 4(b)), (c) single convex (as shown in FIG. 4(c)) or (d) hollow rectangle (as shown in FIG. 4(d)) used to align with the corners 211 of the first stiffener 210. Besides, the alignment marks 122 may be linear, as shown as FIG. 4(e), for single-direction alignment of the first stiffener 210 having a large enough area. The first stiffener 210 is positioned by aligning with the edges of the stiffener 210 and the alignment marks 122.

The flexible substrate 100 is protected from punch damage because the stiffening structure 200 provides sufficient stiffness to support the flexible substrate 100 and the cutting line CL defined on the flexible substrate 100 only passes through the first stiffener 210 to avoid stress concentrations.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A flexible circuit board comprising:
a flexible substrate including a film and a patterned circuit layer located on a top surface of the film and wherein a stiffening area is defined on a bottom surface of the film and
a stiffening structure including a first stiffener and a second stiffener, wherein the first stiffener is disposed on the stiffening area defined on the bottom surface and the second stiffener is disposed on the first stiffener such that the first stiffener is located between the film and the second stiffener, and wherein a cutting line is defined on the flexible substrate so as to only pass through the first stiffener of the stiffening structure, a working area is surrounded by the cutting line, and a non-working area is defined outside the cutting line on the flexible substrate, wherein the working area is separated as a driver integrated circuit (IC) following a punching process along the cutting line.

2. The flexible circuit board in accordance with claim 1, wherein an area of the first stiffener is larger than an area of the second stiffener.

3. The flexible circuit board in accordance with claim 2, wherein a thickness of the first stiffener is more than or equal to a thickness of the second stiffener.

4. The flexible circuit board in accordance with claim 1, wherein the stiffening structure further includes a first adhesive layer and a second adhesive layer, the first adhesive layer is located between the film and the first stiffener and provided for connecting the film and the first stiffener, the second adhesive layer is located between the first and second stiffeners and provided for connecting the first and second stiffeners.

5. The flexible circuit board in accordance with claim 1, wherein the first and second stiffeners are made of polyimide (PI) or polyethylene terephthalate (PET).

6. The flexible circuit board in accordance with claim 1, wherein the second stiffener is completely located on the working area.

7. The flexible circuit board in accordance with claim 6, wherein the first stiffener is located on both of the working area and the non-working area.

8. The flexible circuit board in accordance with claim 6, wherein the patterned circuit layer includes an outer lead section located on the working area, the stiffening area of the bottom surface is located under the outer lead section.

9. The flexible circuit board in accordance with claim 1, wherein the patterned circuit layer includes an alignment mark, an area on the top is defined by a profile of the first stiffener, and a corner of the area is aligned to the alignment mark.

10. The flexible circuit board in accordance with claim 9, wherein the alignment mark is L-shaped or linear.
